(19) United States
(12) Patent Application Publication
(10) Pub. No.: US 2022/0017817 A1
(43) Pub. Date: Jan. 20, 2022

(54) QUANTUM DOT COMPOSITE MATERIAL AND MANUFACTURING METHOD THEREOF, AND LED PACKAGE STRUCTURE

(71) Applicant: Skiileux Electricity Inc., Taoyuan City (TW)

(72) Inventor: CHIEN-SHOU LIAO, New Taipei City (TW)

(21) Appl. No.: 17/376,137

(22) Filed: Jul. 14, 2021

(30) Foreign Application Priority Data
Jul. 15, 2020 (TW) 109123915

(51) Int. Cl. C09K 11/02; H01L 33/50

(52) U.S. Cl. CPC C09K 11/025; B82Y 20/00; H01L 33/502

(57) ABSTRACT

A quantum dot composite material, a manufacturing method thereof and an LED package structure are provided. The quantum dot composite material includes: a plurality of quantum dots, a silicon-containing compound coating layer coating the plurality of quantum dots, and a modified group coordinating and anchoring the silicon-containing compound coating layer. The manufacturing method of the quantum dot composite material includes: a mixing step, a micronization step, and a modifying step, and more specifically: mixing a plurality of quantum dots with polysilazane, micronizing and curing by spray drying, and modifying to obtain the quantum dot composite material. The LED package structure includes a substrate, at least one light-emitting element, and the aforementioned quantum dot composite material.

### CROSS-REFERENCE TO RELATED PATENT APPLICATION

This application claims the benefit of priority to Taiwan Patent Application No. 109123915, filed on Jul. 15, 2020. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a quantum dot composite material and manufacturing method thereof, and more particularly to a quantum dot composite material and manufacturing method thereof and an LED package structure of the quantum dot composite material.

### BACKGROUND OF THE DISCLOSURE

In recent years, with the development of display technology, people have higher demands for the quality of displays. Quantum dots (QDs) have attracted widespread attention from researchers due to their unique quantum confinement effects. Compared with conventional organic light-emitting materials, the quantum dots have the advantages of having a narrow full width at half maximum (FWHM), small particles, no scattering loss, a spectrum that is adjustable with size, and a stable photochemical performance in terms of luminous efficacy. In addition, optical, electrical, and transmission properties of the quantum dots can be adjusted through a synthesis process. The aforementioned advantages have contributed to the importance of quantum dot technology.

However, the method for manufacturing a quantum dot composite material in conventional technology faces problems such as difficulties in manufacturing a uniform quantum dots material, controlling the amount of the quantum dots, and further, the quantum dots material thus obtained has poor stability.

### SUMMARY OF THE DISCLOSURE

In response to the above-referenced technical inadequacies, the present disclosure provides a quantum dot composite material and manufacturing method thereof, and an LED packing structure.

In one aspect, the present disclosure provides a quantum dot composite material that includes a plurality of quantum dots, a silicon-containing compound coating layer coating the plurality of quantum dots, and a modified group coordinating and anchoring the silicon-containing compound coating layer.

In another aspect, the present disclosure provides a method for manufacturing a quantum dot composite material, and the method includes: a mixing step, a micronization step, and a modifying step. Specifically, the mixing step includes mixing a plurality of quantum dots and a polysilazane to form a quantum dots mixture, the micronization step includes micronizing the quantum dots mixture by spray drying, and the modifying step includes mixing a modified material in the quantum dots mixture to obtain the quantum dot composite material.

In yet another aspect, the present disclosure provides a method for manufacturing a quantum dot composite material, and the method includes a mixing step and a micronization step. Specifically, the mixing step is mixing a plurality of quantum dots, a polysilazane and a modified material to form a quantum dots mixture, then micronizing the quantum dots mixture by spray drying in the micronization step to obtain the quantum dot composite material.

Therefore, by virtue of “a modified group coordinating and anchoring the silicon-containing compound coating layer”, the quantum dot composite material of the present disclosure has good stability and the LED package structure thereof has good luminous efficacy.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be good understood by reference to the following description and the accompanying drawings, in which:

FIG. 1A is a schematic view of a quantum dot composite material according to an embodiment of the present disclosure;

FIG. 1B is a schematic view of the quantum dot composite material according to another embodiment of the present disclosure;

FIG. 2 is a schematic view of the quantum dot composite material according to yet another embodiment of the present disclosure;

FIG. 3 is a flowchart of a method for manufacturing the quantum dot composite material of the present disclosure;

FIG. 4 is a flowchart of another method for manufacturing the quantum dot composite material of the present disclosure; and

FIG. 5 is a schematic view of a light-emitting diode (LED) package structure according to an embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

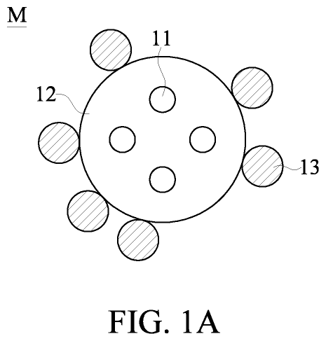

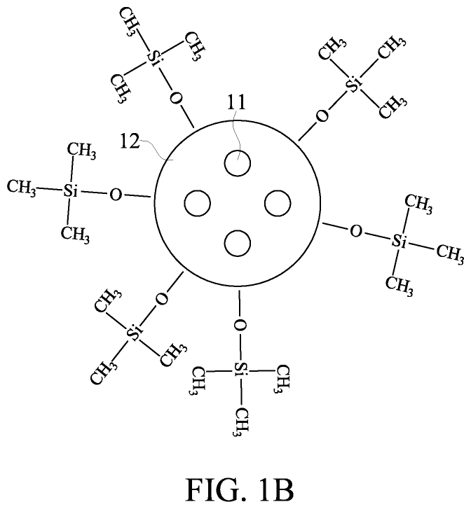

Referring to FIG. 1A to FIG. 1B, the present disclosure provides a quantum dot composite material that includes a plurality of quantum dots 11, a silicon-containing compound coating layer 12 coating the plurality of quantum dots 11, and a modified group 13 coordinating and anchoring the silicon-containing compound coating layer 12.

Specifically, the plurality of quantum dots are selected from the group consisting of group II-VI quantum dots, group III-V quantum dots, and perovskite quantum dots, in which the term “group” refers to an element group of the periodic table. Preferably, the plurality of quantum dots of the present disclosure may be perovskite quantum dots. However, the aforementioned description is merely an example and is not meant to limit the scope of the present disclosure.

For example, the group II-VI quantum dots are selected from the group consisting of CdSe, CdS, CdTe, ZnSe, ZnS, CdTe, ZnTe, CdZnS, CdZnSe, CdZnTe, ZnSeS, ZnSeTe, ZnTeS, CdSeS, CdSeTe, CdTeS, CdZnSeS, CdZnSeTe and CdZnSTe.

For example, the group III-V quantum dots are selected from the group consisting of InP, InAs, GaP, GaAs, GaSb, AlN, AlP, InAsP, InNP, InNSb, GaAlNP and InAlNP.

For example, the perovskite quantum dots are selected from the group consisting of CH₃NH₃PbI₃, CH₃NH₃PbCl₃, CH₃NH₃PbBr₃, CH₃NH₃PbI₂Cl, CH₃NH₃PbICl₂, CH₃NH₃PbI₂Br, CH₃NH₃PbIBr₂, CH₃NH₃PbIClBr, CsPbI₃, CsPbCl₃, CsPbBr₃, CsPbI₂Cl, CsPbICl₂, CsPbI₂Br, CsPbIBr₂ and CsPbIClBr.

In more detail, the modified group 13 reacts with the silicon-containing compound coating layer 12 to form an —O—Si—(R)₃ bond, in which R represents CₙH₂ₙ₊₁, and n is a value between 0 and 5. Furthermore, the modified group 13 is derived from the oxygen bonding between a modified material and the silicon-containing compound coating layer 12. For example, the modified material can be a hexamethyldisilazane (HDMS) or a hydrophobic silazane having an alkyl group of 2 to 5 carbons (C2-C5).

Reference is made to FIG. 1B, which is a schematic view of the modified material being HDMS. The hexamethyldisilazane and the silicon-containing compound coating layer 12 form a chemical reaction, as shown in the following reaction formula:

2SiOH+[(CH₃)₃Si]₂NH→2SiO[Si(CH₃)₃]2+NH₃.

However, the aforementioned description is merely an example and is not meant to limit the scope of the present disclosure.

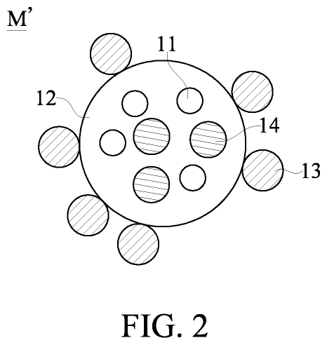

Referring to FIG. 2, the present disclosure further provides another quantum dot composite material that includes a modified material 14. In other words, as shown in FIG. 2, the quantum dot composite material includes a plurality of quantum dots 11, a silicon-containing compound coating layer 12, a modified group 13, and a modified material 14 covered in the silicon-containing compound coating layer 12. That is to say, one part of the modified material 14 and the silicon-containing compound coating layer 12 form a bonding of the modified group 13, and another part of the modified material 14 that is not bonded with the silicon-containing compound coating layer 12 is also covered in the silicon-containing compound coating layer 12.

Preferably, a particle size of the quantum dot composite material of the present disclosure is between 50 nm and 5 μm.

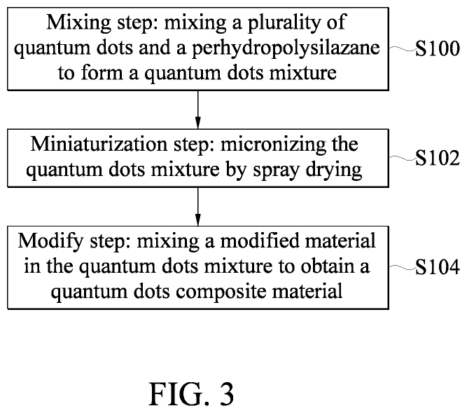

Referring to FIG. 3, the present disclosure provides a method for manufacturing a quantum dot composite material, the method includes a mixing step S100, a micronization step S102, and a modify step S104. Specifically, the mixing step S100 is mixing a plurality of quantum dots and a polysilazane to form a quantum dots mixture, then micronizing the quantum dots mixture by spray drying in the micronization step S102, and finally mixing a modified material in the quantum dots mixture through the modify step S104 to obtain the quantum dot composite material.

More specifically, a content ratio relative to a total mass of the quantum dot composite material is not particularly limited. Preferably, the content ratio of the plurality of quantum dots to the total composition is usually 0.01 to 10 wt %. In this range, good aggregation characteristics can be provided, and good luminescence can be maintained. Furthermore, a particle size of each of the plurality of quantum dots on average is not particularly limited; preferably, the particle size can be 1 nm to 50 nm or less, for maintaining a good crystal structure.

Optionally, a solvent may be further added as a medium for dispersing the plurality of quantum dots. For example, esters such as methyl formate, ethyl formate, propyl formate, pentyl formate, methyl acetate, ethyl acetate, and pentyl acetate; ketones such as γ-butyrolactone, N-methyl-2-pyrrolidone, acetone, dimethyl ketone, diisobutyl ketone, cyclopentanone, cyclohexanone, methylcyclohexanone, etc.; ether such as diethyl ether, methyl tert-butyl ether, diisopropyl ether, dimethoxymethane, dimethoxyethane, 1,4-dioxane, 1,3-dioxolane, 4-methyldioxolane, tetrahydrofuran, methyltetrahydrofuran, anisole, phenylethyl ether, etc.; alcohol such as methanol, ethanol, 1-propanol, 2-propanol, 1-butanol, 2-butanol, tert-butanol, 1-pentanol, 2-methyl-2-butanol, methoxypropanol, diacetone alcohol, cyclohexanol, 2-fluoroethanol, 2,2,2-trifluoroethanol, 2,2,3,3-tetrafluoro-1-propanol, etc.; organic solvents with amide groups, such as ethylene glycol monomethyl ether, ethylene glycol monoethyl ether, ethylene glycol monobutyl ether, ethylene glycol monoethyl ether acetate, triethylene glycol dimethyl ether; organic solvents with amido groups, such as N,N-dimethylformamide, acetamide, N,N-dimethylacetamide, etc.; organic solvents with nitrile groups, such as acetonitrile, isobutyronitrile, propionitrile, methoxyacetonitrile, etc.; organic solvents with carbonate groups, such as ethylene carbonate, propylene carbonate, etc.; organic solvents with halogenated hydrocarbon groups, such as dichloromethane, chloroform, etc.; organic solvents with hydrocarbon groups, such as n-pentane, cyclohexane, n-hexane, benzene, toluene, xylene, etc.; dimethyl sulfoxide, etc.

Furthermore, polysilazane is used to provide a silicon source to form silicon oxide, silicon nitride, or silicon oxynitride of the silicon-containing compound coating layer to cover the plurality of quantum dots. Preferably, a weight ratio of polysilazane to quantum dots is 10:1 to 1000:1, so as to obtain the silicon-containing compound coating layer with a coating thickness from 10 nm to 10 μm. The formula of polysilazane is: —[R¹R²Si—NR₃]—, in which R¹, R², and R³ each independently represent a hydrogen atom, alkyl group, alkenyl group, cycloalkyl group, aryl group, alkylsilyl group, alkylamino group, or alkoxy group. Preferably, the polysilazane of the present disclosure has a molecular weight from 200 to 3000. When R¹, R², and R³ are all hydrogen atoms, the molecular formula of polysilazane is: —[H₂Si—NH]ₙ—, and is called as perhydropolysilazane (PHPS), also known as inorganic polysilazane. When R¹, R², and R³ each represent an organic group, the polysilazane is called organic polysilazane. Preferably, the polysilazane of the present disclosure may be PHPS, which provides a good refractive index.

The micronization step S102 is a spray drying process to remove liquid medium from a dispersion by spray drying with a carrier gas selected from air, inert gas (such as argon) or nitrogen at an inlet temperature set to be from 150° C. to 500° C. The dispersion is cured into quantum dots microspheres coated with silicon compound. Preferably, the carrier gas is nitrogen, and a pressure can be from 0.20 MPa to 0.50 MPa. The nozzle speed can be from 500 ml/hour to 3000 ml/hour, from 1000 ml/hour to 2000 ml/hour, or about 1760 ml/hour.

Preferably, an average particle size of silica-coated quantum dots microspheres manufactured by the spray drying process is between 10 nm and 10 μm, depending on the ratio of the solution formulation and the reaction conditions of the spray drying manner.

In the modify step S104, the modified material is mixed with the quantum dots mixture. The modified material can be hexamethyldisilazane or a hydrophobic silazane having an alkyl group of 2 to 5 carbons, for example, such as tetramethyldisilazane, hexarthyl disilazane, etc.

The modified material reacts with the quantum dots mixture to ligand anchor the silicon-containing compound coating layer, and further forms an —O—Si—(R)₃ bond, in which R represents CₙH₂ₙ₊₁, and n is a value between 0 and 5.

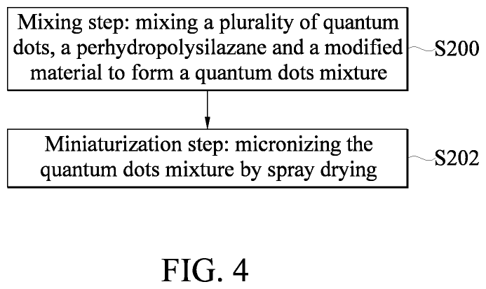

Referring to FIG. 4, the present disclosure further provides a method for manufacturing a quantum dot composite material, the method includes a mixing step S200 and a micronization step S202. Specifically, the mixing step S200 is mixing a plurality of quantum dots, a polysilazane, and a modified material to form a quantum dots mixture, then micronizing the quantum dots mixture by spray drying in the micronization step S202 to obtain a quantum dot composite material.

More specifically, comparing FIG. 4 with FIG. 3, the method for manufacturing a quantum dot composite material in FIG. 4 shows that the modified material is added in the mixing step S200, so that the plurality of quantum dots 11, the silicon-containing compound coating layer 12, the modified group 13, and the modified material 14 covered in the silicon-containing compound coating layer 12 are formed. That is to say, one part of the modified material 14 and the silicon-containing compound coating layer 12 form a bonding of the modified group 13, and the other part of the modified material 14 that is not bonded with the silicon-containing compound coating layer 12 is also covered in the silicon-containing compound coating layer 12.

Contents of the micronization step S202 is the same as above-mentioned, and will not be reiterated herein.

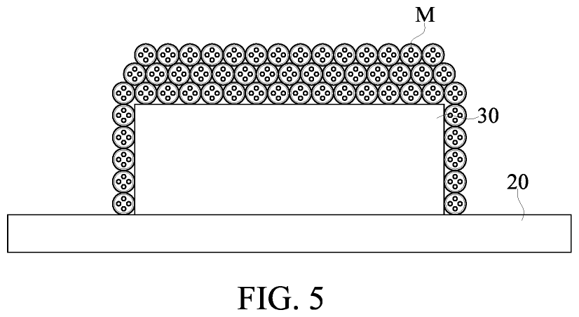

Referring to FIG. 5, the present disclosure provides an LED package structure that includes a substrate 20, at least one light-emitting element 30, and a quantum dot composite material M covering the at least one light-emitting element. The at least one light-emitting element 30 is disposed on one surface of the substrate 20, and the quantum dot composite material M covers the at least one light-emitting element 30.

Preferably, the quantum dot composite material M covers a surface and a side of the at least one light-emitting element 30 that are relative to the substrate 20, details regarding the materials and configurations of the quantum dot composite material M are the same as above-mentioned, and will not be reiterated herein.

Further, the at least one light-emitting element 30 can be, for example, LED chips. The LED package structure can include at least one light-emitting element or multiple light-emitting elements, and the multiple light-emitting elements can be connected in series or in parallel.

Optionally, the LED package structure further includes wirings formed on at least an upper surface of the structure, and may also be formed on an inside and/or side surface and/or bottom surface of the structure. Furthermore, the wirings preferably have an element mounting portion for mounting the light-emitting element, a terminal portion for external connection, a lead-out wiring portion for connecting the above-mentioned, and the like.

### Beneficial Effects of the Embodiments

In conclusion, by virtue of “a modified group coordinating and anchoring the silicon-containing compound coating layer”, the quantum dot composite material of the present disclosure has good stability and the LED package structure thereof has good luminous efficacy.

Furthermore, the modified group coordinates and anchors the silicon-containing compound coating layer to produce —O—Si—(R)₃ bonding, which effectively increases the stability of the quantum dot composite material and maintains the luminous efficacy of the LED package structure.

In addition, the method for manufacturing a quantum dot composite material of the present disclosure is simple, safe, involves easy operation, and has excellent application prospects. Furthermore, the “micronization step: micronizing the quantum dots mixture by spray drying” can further increase the uniformity of the quantum dot composite material.

Moreover, the LED package structure of the present disclosure can effectively improve the quantum efficiency of the LED package structure through the quantum dot composite material, and further increase the luminous efficiency.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated.

Alternative embodiments will become apparent to those skilled in the art to which the present disclosure pertains without departing from its spirit and scope.

What is claimed is:

1. A quantum dot composite material comprising:
a plurality of quantum dots;
a silicon-containing compound coating layer being coated upon the plurality of quantum dots, and the silicon-containing compound coating layer being formed by polysilazane; and
a modified group coordinating and anchoring the silicon-containing compound coating layer to form an —O—Si—(R)₃ bond, wherein R represents CₙH₂ₙ₊₁, and n is a value between 0 and 5;
wherein a part of the plurality of quantum dots contact with each other.

2. The quantum dot composite material according to claim 1, further comprising a modified material having a same functional group as the modified group and being coated in the silicon-containing compound coating layer.

3. The quantum dot composite material according to claim 2, wherein the modified material is a hexamethyldisilazane or a hydrophobic silazane having an alkyl group of 2 to 5 carbons.

4. The quantum dot composite material according to claim 1, wherein the plurality of quantum dots are selected from group II-VI quantum dots, group III-V quantum dots and perovskite quantum dots.

5. The quantum dot composite material according to claim 4, wherein the group II-VI quantum dots are selected from the group consisting of CdSe, CdS, CdTe, ZnSe, ZnS, CdTe, ZnTe, CdZnS, CdZnSe, CdZnTe, ZnSeS, ZnSeTe, ZnTeS, CdSeS, CdSeTe, CdTeS, CdZnSeS, CdZnSeTe and CdZnSTe quantum dots.

6. The quantum dot composite material according to claim 4, wherein the group III-V quantum dots are selected from the group consisting of InP, InAs, GaP, GaAs, GaSb, AlN, AlP, InAsP, InNP, InNSb, GaAlNP and InAlNP quantum dots.

7. The quantum dot composite material according to claim 4, wherein the perovskite quantum dots are selected from the group consisting of CH₃NH₃PbI₃, CH₃NH₃PbCl₃, CH₃NH₃PbBr₃, CH₃NH₃PbI₂Cl, CH₃NH₃PbICl₂, CH₃NH₃PbI₂Br, CH₃NH₃PbIBr₂, CH₃NH₃PbIClBr, CsPbI₃, CsPbCl₃, CsPbBr₃, CsPbI₂Cl, CsPbICl₂, CsPbI₂Br, CsPbIBr₂ and CsPbIClBr quantum dots.

8. A method for manufacturing a quantum dot composite material, comprising:
mixing step: mixing a plurality of quantum dots, a polysilazane and a modified material to form a quantum dots mixture, wherein the polysilazane forms a silicon-containing compound coating layer coating the plurality of quantum dots;
micronization step: micronizing the quantum dots mixture by spray drying; and
modifying step: mixing a modified material in the quantum dots mixture, the modified material coordinating and anchoring the silicon-containing compound coating layer to obtain the quantum dot composite material;
wherein the modified material is a hexamethyldisilazane or a hydrophobic silazane having an alkyl group of 2 to 5 carbons;
wherein a part of the plurality of quantum dots contact with each other.

9. The method according to claim 8, wherein the modified material reacts with the silicon-containing compound coating layer to form an —O—Si—(R)₃ bond, wherein R represents CₙH₂ₙ₊₁, and n is a value between 0 and 5.

10. A method for manufacturing a quantum dot composite material, comprising:
mixing step: mixing a plurality of quantum dots, a polysilazane and a modified material to form a quantum dots mixture, wherein the polysilazane forms a silicon-containing compound coating layer coating the plurality of quantum dots and a part of the modified material, and another part of the modified material coordinate anchors with the silicon-containing compound coating layer; and
micronization step: micronizing the quantum dots mixture by spray drying to obtain the quantum dot composite material;
wherein the modified material is a hexamethyldisilazane or a hydrophobic silazane having an alkyl group of 2 to 5 carbons;
wherein a part of the plurality of quantum dots contact with each other.
